(19) United States
(12) Patent Application Publication
(10) Pub. No.: US 2016/0049517 A1
(43) Pub. Date: Feb. 18, 2016

(54) THIN FILM TRANSISTOR AND DISPLAY PANEL USING THE SAME

(71) Applicant: INNOLUX CORPORATION, MIAO-LI COUNTY (TW)

(72) Inventors: KUAN-FENG LEE, MIAO-LI COUNTY (TW); KUO-CHANG CHIANG, MIAO-LI COUNTY (TW); TZU-MIN YAN, MIAO-LI COUNTY (TW)

(21) Appl. No.: 14/809,327

(22) Filed: Jul. 27, 2015

(30) Foreign Application Priority Data
Aug. 18, 2014 (TW) 103128293

(51) Int. Cl. H01L 29/786; H01L 27/12; H01L 29/423; H01L 29/24

(52) U.S. Cl. CPC H01L 29/7869; H01L 29/24; H01L 29/78696; H01L 29/78606; H01L 27/1225; H01L 29/42356; H01L 29/42384

(57) ABSTRACT

A thin film transistor includes a gate electrode, a gate insulating layer, a source electrode, a drain electrode, and a channel layer. The gate electrode is disposed on a substrate, and the channel layer is electrically insulated from the gate electrode. The gate insulating layer is disposed between the gate electrode and the channel layer. The source electrode and the drain electrode are electrically connected with the channel layer. The channel layer includes a front channel layer proximate to a side of the gate insulating layer, a back channel layer proximate to a side of the source electrode and an intermediate layer between the front channel layer and the back channel layer. The oxygen vacancy concentration of the front channel layer is greater than the oxygen vacancy concentration of the intermediate layer

### BACKGROUND

1. Field of the Invention

The instant disclosure relates to a structure of a thin film transistor, in particular, relates to a thin film transistor compatible with a display panel.

2. Description of Related Art

Most thin film transistor liquid crystal displays include an active element array substrate, a color filter substrate, and a backlight module. The active element array substrate is formed by disposing thin film transistors that control voltage of sub-pixels, so as to adjust the angle of the rotation of liquid crystal. Then, the gray scale (brightness) of sub-pixels can also be adjusted by polarizer films. Through the color filter compatible with the grey scale of sub-pixels, the sub-pixels emitting red, blue and green light can produce imagery.

When voltage is applied to a thin film transistor, if the curve of current change with applied voltages from high to low does not match with that of current change with applied voltages from low to high, the phenomenon of hysteresis occurs. Thin film transistors in the presence of hysteresis will cause inconsistent rotation angels of liquid crystals under the same applied voltage, which will further lead to inconsistent brightness in the display panel at the same grey scale, thus, rendering flicker or image sticking on the display panel.

### SUMMARY OF THE INVENTION

An embodiment of the instant disclosure provides a channel layer of a thin film transistor that can reduce the effect of hysteresis.

An embodiment of the instant disclosure provides a thin film transistor that includes a gate electrode, a gate insulating layer, a drain electrode, a source electrode, and a channel layer. The gate electrode is disposed on a substrate, and the channel layer is electrically insulated from the gate electrode. The gate insulating layer is disposed between the gate electrode and the channel layer. Both of the drain electrode and the source electrode are electrically connected with the channel layer. The channel layer includes a front channel layer proximate to a side of the gate insulating layer, a back channel layer proximate to a side of the source electrode and the drain electrode, and an intermediate layer between the front channel layer and the back channel layer. The oxygen vacancy concentration of the front channel layer is greater than the oxygen vacancy concentration of the intermediate layer.

An embodiment of the instant disclosure provides a display panel that includes a first substrate, a second substrate, and an active element array layer. The active element array layer is disposed between the first and the second substrates. The active element array layer includes a plurality of thin film transistors. At least one of the thin film transistors includes the gate electrode, the gate insulating layer, the drain electrode, the source electrode and the channel layer. The gate electrode is disposed on a substrate. The channel layer is electrically insulated from the gate electrode, and the gate insulating layer is disposed between the gate electrode and the channel layer. Both of the drain electrode and the source electrode are electrically connected to the channel layer. The channel layer includes a front channel layer proximate to a side of the gate insulating layer, a back channel layer proximate to a side of the source electrode and the drain electrode, and an intermediate layer between the front channel layer and the back channel layer. The oxygen vacancy concentration of the front channel layer is greater than the oxygen vacancy concentration of the intermediate layer.

In summary, the instant disclosure provides the channel layer with annealing treatment after deposition. The temperature of annealing treatment ranges between 200° C. and 400° C. The front channel layer is defined as a portion of the channel layer proximate to a side of the gate insulating layer where the binding energy of the channel layer starts to shift. The back channel layer is defined as a portion of the channel layer proximate to a side of the source electrode and the drain electrode where the binding energy of the channel layer starts to shift. The channel layer can be separated into three portions from the front channel layer to the back channel layer: the first zone, the second zone, and the third zone. The first zone represents a portion of the channel layer proximate to the front channel layer, the third zone represents the channel layer proximate to the back channel layer, and the second zone represents the intermediate layer located between the front channel layer and the back channel layer. The oxygen vacancy concentrations in both of the first zone and the third zone are independently larger than oxygen vacancy concentration in the second zone. In this way, most oxygen vacancies exist in the front channel layer and the back channel layer. It's worth mentioning that during the heat treatment in the channel layer, the oxygen vacancies that existed in the intermediate layer shift to the front channel layer and the back channel layer, so as to improve upon the hysteresis phenomenon. Therefore, the response speed of a liquid crystal display as well as flicker or image sticking will be improved.

An embodiment of the instant disclosure provides a thin film transistor compatible with various display panels, and by improving upon the effect of hysteresis, the response speed of a liquid crystal display (LCD) and the flicker or image sticking of the display panel is also improved.

In order to further understand the techniques, means and effects of the instant disclosure, the following detailed descriptions and appended drawings are hereby referred to, such that through which, the purposes, features and aspects of the instant disclosure can be thoroughly and concretely appreciated; however, the appended drawings are merely provided for reference and illustration, without any intention to be used for limiting the instant disclosure.

### BRIEF DESCRIPTION OF THE DRAWINGS

FIG. 1 illustrates a cross-sectional view of a thin film transistor in accordance with a first embodiment of the present disclosure.

FIG. 2 is a schema illustrating atomic percentages in the channel layer with respect to changes in depth.

FIG. 3A is a schema illustrating atomic percentages of Ols intensity of the channel layer 130 with respect to changes in depth

FIG. 3B is a schema illustrating atomic percentages of Ols intensity of the channel layer 130 with respect to changes in depth.

FIG. 4A shows the Ols XPS spectrum in the front channel layer.

FIG. 4B shows the Ols XPS spectrum in the intermediate channel layer.

FIG. 4C shows the Ols XPS spectrum in the back channel layer.

FIG. 5A is a schema illustrating hysteresis of the current-voltage curve for thin film transistors having a channel layer with heat treatment.

FIG. 5B is a schema illustrating hysteresis in the current-voltage curve for thin film transistors having a channel layer without heat treatment.

FIG. 6 illustrates a structural prospective view of a display panel in accordance with an embodiment of the instant disclosure.

### DETAILED DESCRIPTION OF THE PREFERRED EMBODIMENTS

In the accompanying drawings, some exemplary embodiments are shown, and a more detailed description of various embodiments with reference to the accompanying drawings in accordance with the present disclosure is set forth below. It is to be understood that the concept of the invention may be embodied in many different forms and should not be construed as limited to the embodiment set forth herein. To be more precise, the exemplary embodiments set forth herein are provided to a person of ordinary skilled in the art to thoroughly and completely understand contents disclosed herein and fully provide the spirit of the invention. In each of the drawings, the relative size, proportions, and depiction of the layers and regions in the drawings may be exaggerated for clarity and precision, and like numerals indicate like elements.

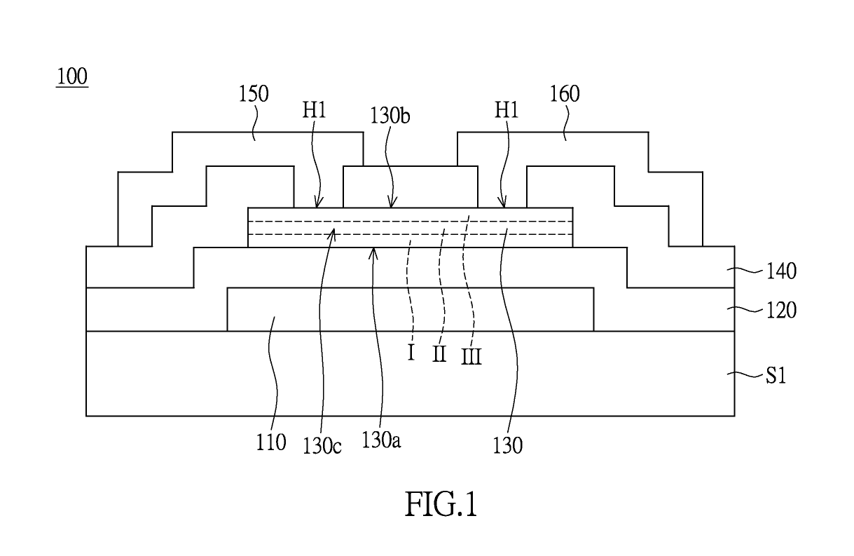

FIG. 1 illustrates a cross-sectional view of a thin film transistor in accordance with the first embodiment of the present disclosure. Please refer to FIG. 1. In the embodiment of the present disclosure, the thin film transistor 100 is a bottom gate thin film transistor and the thin film transistor 100 includes a gate electrode 110, a gate insulating layer 120, a channel layer 130, a protective layer 140, a source electrode 150, and a drain electrode 160, all of which are sequentially formed on a substrate S1. The protective layer 140 covers part of the channel layer 130 and exposes another part of the channel layer 130 that is electrically connected with both the source electrode 150 and the drain electrode 160.

In general, when voltage is applied to the gate electrode 110, electrons will be induced to form the channel layer 130. The gate insulating layer 120 insulates the channel layer 130 from the gate electrode 110 to prevent the thin film transistor 100 from short circuiting. The protective layer 140 is used as the etch stop layer for the channel layer 130.

In general, the substrate S1 is used as a support member of the thin film transistor 100 and may be a silicon substrate, a sapphire substrate, a ceramic substrate or a glass substrate. Therefore, the present disclosure does not limit the type of substrate S1.

The gate electrode 110 is disposed on the substrate S1. The gate electrode 110 may have either a single-layer structure or a stacked-layer structure with more than two layers. In this embodiment, the gate electrode 110 has a single-layer structure. The gate electrode 110 may be made of metallic material, such as Copper (Cu), Aluminum (Al), Titanium (Ti), Tantalum (Ta), Tungsten (W), Molybdenum (Mo), Chromium (Cr), Niobium (Nb) or/and the like. Alternatively, the gate electrode 110 may be made of alloy, such as aluminium-molybdenum alloy or/and aluminum-niobium alloy. Alternatively, the gate electrode 110 may be made of metal nitride, such as tantalum nitride (TaN), and aluminum nitride (AlN) or/and the like.

The gate insulating layer 120, which is disposed above the gate electrode 110, covers both the gate electrode 110 and at least partial of the substrate S1. The gate insulating layer 120 may have either a single-layer structure or a stacked-layer structure with more than two layers. In this embodiment, the gate insulating layer 120 has a single-layer structure. The material of the gate insulating layer 120 may be silicon oxide (SiOₓ), silicon nitride (SiNₓ), and/or silicon oxynitride (SiON).

The protective layer 140 is disposed above the channel layer 130. The material of the protective layer 140 may be silicon oxide (SiOₓ). Through photolithography techniques, the protective layer 140 is patterned and a plurality of openings H1 is created. The source electrode 150 and the drain electrode 160 can be electrically connected to the channel layer 130 through the openings H1.

The channel layer 130 is located between the gate insulating layer 120 and the protective layer 140 and the channel layer 130 is electrically insulated from the gate electrode 110. The channel layer 130 is a semiconductor layer and can be made of amorphous silicon (a-Si), microcrystalline silicon (mc-Si), poly silicon, or metal oxide and the like. In one embodiment, the channel layer 130 is a metal oxide semiconductor layer. To be specific, a metal oxide film is formed by sputtering process, and then an island-shaped metal oxide semiconductor 130 is produced by photolithography techniques in successive process. It is worth mentioning that the materials of the channel layer 130 is selected from indium-gallium-zinc oxide, zinc oxide, stannous oxide, indium-zinc oxide, gallium-zinc oxide, zinc-tin oxide, indium-tin oxide, or mixtures thereof In this embodiment, the material of the channel layer 130 is indium-gallium-zinc oxide. The instant disclosure does not limit the materials of channel layer 130.

To be specific, the channel layer 130 can be made by different production procedures, such as magnetron sputtering, metal organic chemical-vapor deposition or pulsed laser deposition. After the deposition process, the channel layer 130 will be heat treated, such as annealing. The temperature of annealing treatment will range between 200° C. and 400° C.

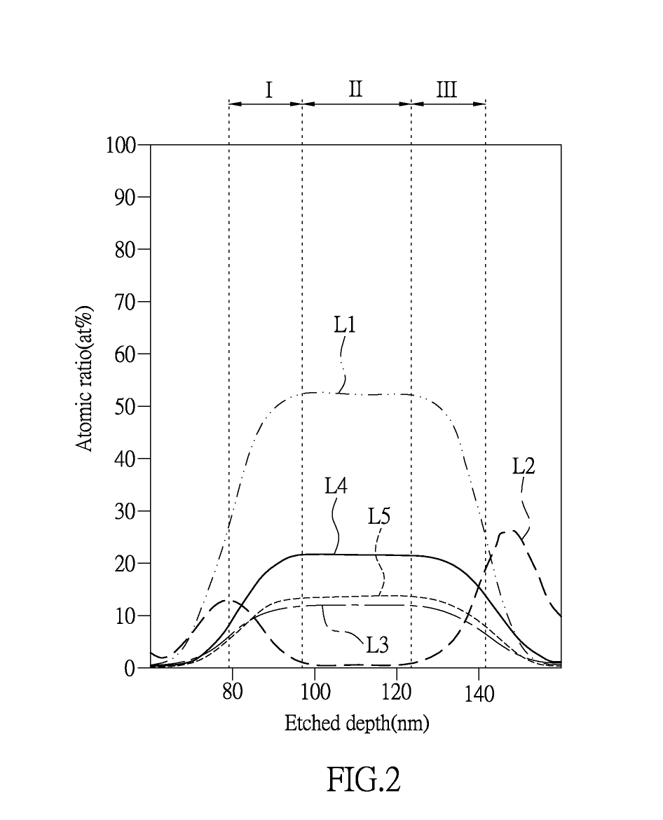

Notably, the composition of the channel layer 130 can be understood by x-ray photoelectron spectroscope (XPS). FIG. 2 is a schema illustrating atomic ratio in the channel layer 130 with respect to changes in depth. The Table 1 below shows the ranges of stoichiometric ratio for different atoms and the ranges of atomic ratio of indium (In), gallium (Ga), zinc (Zn), and oxygen (O) in the channel layer 30.

TABLE 1

| At % | In | Ga | Zn | O | stoichiometric ratio |
|---|---|---|---|---|---|
| channel layer | 11.9~12.5% | 17.5~21.3% | 12~15.3% | 53.9~56.8% | In₁Ga_{1.5~1.8}Zn_{1~1.2}O_{4.3~4.6} |

Please refer to FIG. 2 and Table 1. The channel layer 130 is analyzed through x-ray photoelectron spectroscope, and the material of the channel layer 130 is indium-gallium-zinc oxide. The XPS depth profile is accomplished by ion beam sputtering on specimen and analyzing the electrical signals at different depths to obtain the composition of elements at different depths. In FIG. 2, x-axis represents the depth of the channel layer 130 from the side proximate to the protective layer 140 to the side proximate to the gate insulating layer 120, whereas y-axis represents atomic percentage (at %). The unit of x-axis is the etched depth, namely the depth of the specimen is analyzed by ion-sputtering. The Curve L1 represents the atomic percentage variation of Ols bonding with respect to changes in depth. The Curve L2 represents the atomic percentage variation of oxygen vacancy concentration of the channel layer 130 with respect to changes in depth. The Curve L3 represents the atomic percentage variation of In—O bonding with respect to changes in depth. The Curve L4 represents the atomic percentage variation of Ga₂O₃ bonding with respect to changes in depth. The Curve L5 represents the atomic percentage variation of Zn—O bonding with respect to changes in depth.

The variations of each Curve L1-L5 are shown in FIG. 2 and curves also illustrate the atomic percentage variation at different thickness of the channel layer 130. The variation of Curve L1 and Curve L3-5 are not significant, namely, the atomic percentage of indium, gallium, zinc, and oxygen are not significant with respect to changes in depth of the channel layer 130. Please refer to Table 1. The channel layer 130 is a Indium-Gallium-Zinc Oxide layer, in which the ratio of indium, gallium, zinc, and oxygen is 1:1.45 to 1.8:1 to 1.25:4.3 to 4.7 (1:1.45-1.8:1-1.25:4.3-4.7). Curve L2 shows that the variations at the junction between the channel layer 130 and the gate insulating layer 120 and at the junction between the channel layer 130 and the protective layer 140 are wider than that at the interior portions the channel layer 130. Namely, more oxygen vacancies exist near the surfaces of the channel layer 130 proximate to the sides of gate insulating layer 120 and the protective layer 140 than at the interior portions of channel layer 130.

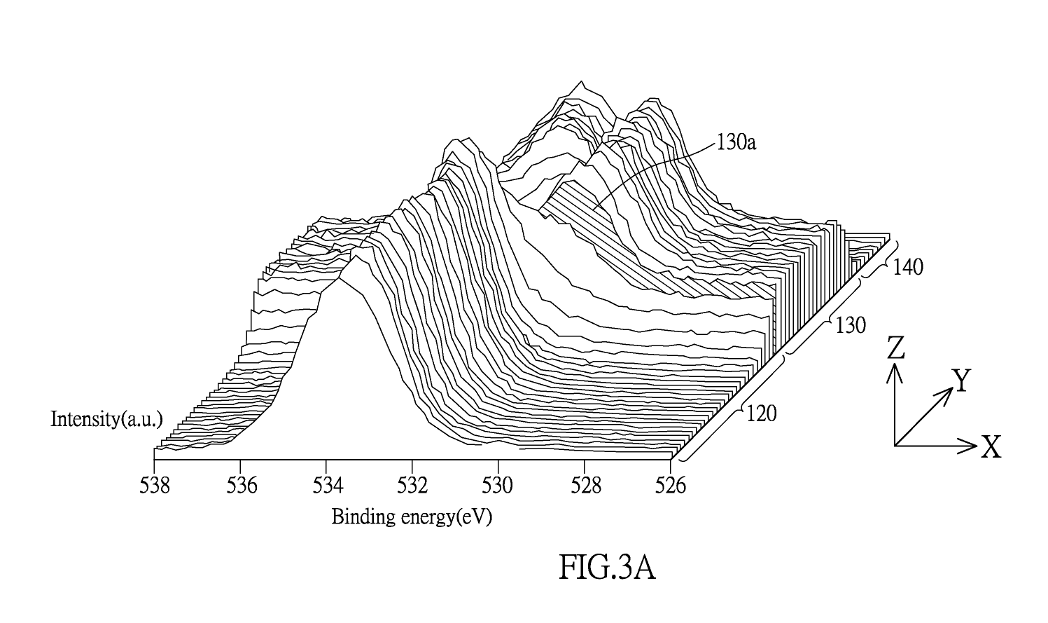

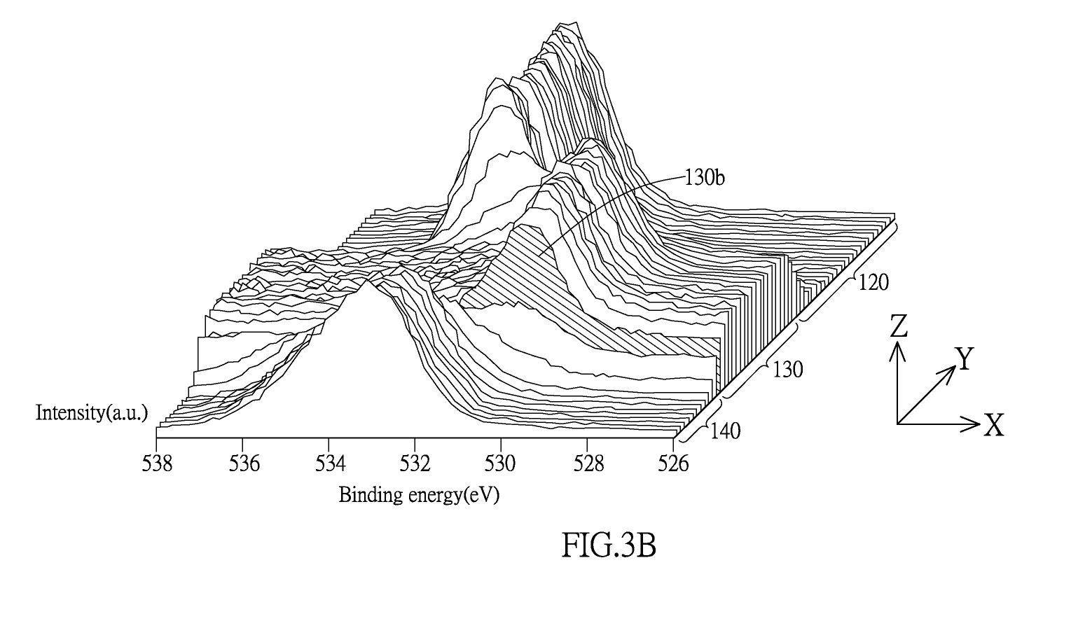

FIG. 3A and 3B are schemas illustrating atomic percentages of Ols bonding of the channel layer 130 with respect to changes in depth. The bonding ratios illustrated in FIGS. 3A and 3B are correspondingly shown in details in Table 2 as follows. In FIGS. 3A and 3b, x-axis represents the value of binding energy in units of eV in the instant embodiment, z-axis represents the value of intensity in units of a.u., absorbance unit in the instant embodiment, and y-axis represents the depth of the channel layer 130. In FIG. 3A, the y-axis illustrates the view from the side proximate to the gate insulating layer 120 to the side proximate to the protective layer 140. In FIG. 3B, the y-axis illustrates the view from the side proximate to the protective layer 140 to the side proximate to the gate insulating layer 120.

The curves shown in FIG. 3A and 3B represent the spectra variation of Ols bonding in the channel layer 130 with respect to changes in depth. The binding energy peaks of Ols bonding of the channel layer 130 shift with respect to the changes in depth. The binding energy peaks of Ols bonding of the channel layer 130, as viewed from the side proximate to the gate insulating layer 120 to the side proximate to the protective layer 140, shift from a low position to a relatively higher position and then shift to a lower position. An front channel layer 130a is defined as the channel layer 130 proximate to a side of the gate insulating layer 120 where the binding energy of the channel layer starts to shift. An back channel layer 130b is defined as the channel layer 130 proximate to a side of the protective layer 140 or the source electrode 150 and the drain electrode 160 where the binding energy of the channel layer 130 starts to shift. An intermediate layer 130c is defined as the part of channel layer 130 between the front channel layer 130a and the back channel layer 130b. The thicknesses of the front channel layer 130a and the back channel layer 130b range between 1 nanometer and 10 nanometers, and the thickness of the intermediate layer 130c is much larger than the thickness of the front channel layer 130a as well as the thickness of the back channel layer 130b.

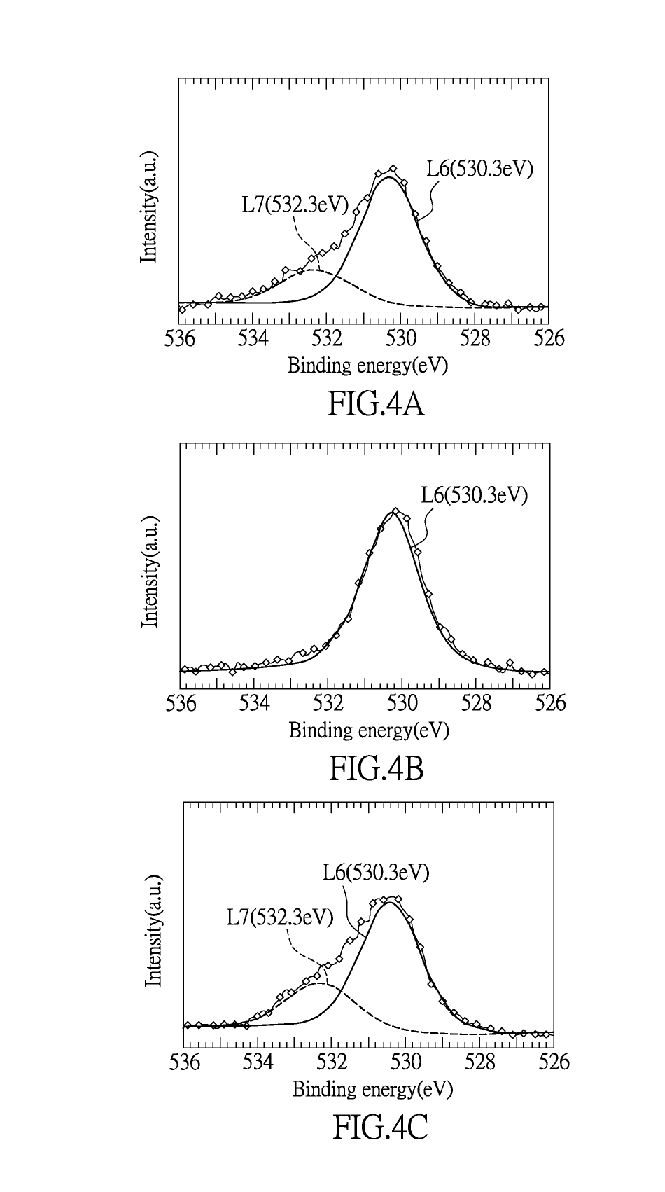

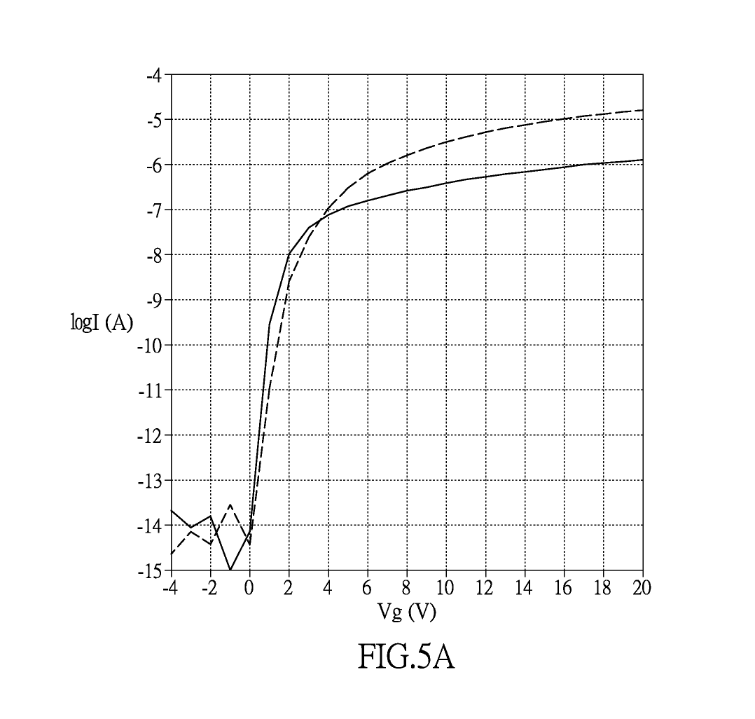

In order to articulate the characteristics and the composition of the channel layer 130, Ols bonding of the intermediate layer 130c, the front channel layer 130a, and the back channel layer 130b can be analyzed with curve fitting applied. FIG. 4A shows the Ols XPS spectrum at the front channel layer 130a. FIG. 4B shows the Ols XPS spectrum at the intermediate channel layer 130c. FIG. 4C shows the Ols XPS spectrum at the back channel layer 130b. The Ols bonding in the intermediate layer 130c is approximately symmetric, whereas the Ols bonding in the front channel layer 130a and the back channel layer 130b are asymmetric, which implies the front channel layer 130a and the back channel layer 130b are not only consisted of oxygen lattices (530.3 eV) but oxygen vacancies (532.3 eV). The fitted curve L6 represents the peak of variation curve of oxygen lattices (530.3 eV). The fitted curve L7 represents the peak of variation curve of oxygen vacancy (532.3 eV). The fitted curves L6 and L7, shown in FIGS. 4A and 4C, illustrates that oxygen vacancies exist in both the front channel layer 130a and the back channel layer 130b. In

FIG. 4B, only the fitted curve L6 existed demonstrates that almost no oxygen vacancies exist in the intermediate layer 130c. The following elements content in Table 2 is obtained by integrating the area under the fitted curves L6 and L7 respectively in FIGS. 4A and 4C.

TABLE 2

| | The front channel | | The back channel | |
|---|---|---|---|---|
| | layer 130a | | layer 130b | |
| | oxygen | oxygen | oxygen | oxygen |
| | vacancy | concentration | vacancy | concentration |
| | concen- | without | concen- | without |
| | tration | oxygen | tration | oxygen |
| | (L6) | vacancy (L7) | (L6) | vacancy (L7) |
| percentage | 20.2% | 79.8% | 6.3% | 93.7% |
| of bond | | | | |

Please refer to FIG. 2 again. According to Curve L2, the oxygen vacancy concentrations at both the side of the channel layer 130 proximate to the gate insulating layer 120 (namely, the front channel layer 130a) and the side of the channel layer 130 proximate to the protective layer 140 or the source electrode 150 and the drain electrode 160 (which is the back channel layer 130b) are higher than the oxygen vacancy concentration at the interior portions of the channel layer 130 (namely, the intermediate layer 130c). The channel layer 130 can be basically separated into three portions from the front channel layer 130a to the back channel layer 130b: the first zone I, the second zone II and the third zone III. The first zone I represents a portion of the channel layer 130 proximate to the front channel layer 130a, the third zone III represents the a portion of the channel layer 130 proximate to the back channel layer 130b, and the second zone II represents the intermediate layer 130c located between the first zone I (proximate to the front channel layer 130a) and the third zone III (proximate to the back channel layer 130b). According to the variations between the first, second and third zones I, II, and III in curve L2, the oxygen vacancy concentration in the first zone I and the oxygen vacancy concentration in the third zone III are independently larger than the oxygen vacancy concentration in the second zone II. Therefore, the oxygen vacancies of the front channel layer 130a and the back channel layer 130b are independently larger than oxygen vacancy in the intermediate layer 130c. In this way, most oxygen vacancies exist in the front channel layer 130a and the back channel layer 130b. The oxygen vacancy concentrations of the front channel layer 130a and the back channel layer 130b are between 3% and 20%.

In addition, oxygen vacancies in the back channel layer 130b are not equally distributed. Since multiple openings H1 are formed through photolithography techniques, the part of the channel layer 130 connected to the openings H1 is damaged by photolithography techniques, which makes the oxygen vacancy concentration of a portion of the channel layer 130 connected to the openings H1 greater than the oxygen vacancy concentration of a portion of the channel layer 130 connected to the protective layer 140.

Notably, during the process of heat treatment, the oxygen vacancies presented in the intermediate layer 130c shift to the front channel layer 130a and the back channel layer 130b, thus, improving the hysteresis phenomenon.

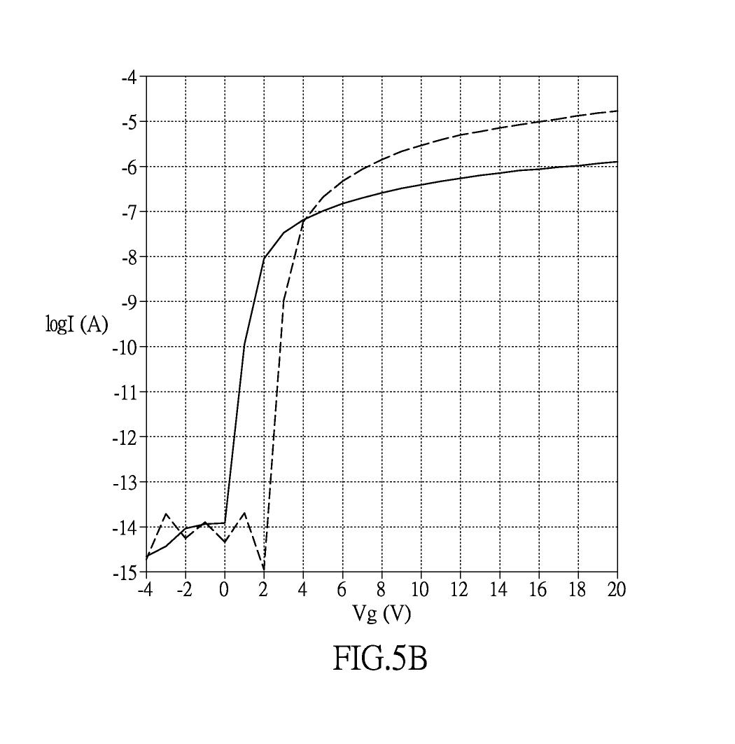

FIG. 5A is a schema illustrating hysteresis of the current-voltage curve for thin film transistors having a channel layer with heat treatment. FIG. 5B is a schema illustrating hysteresis in the current-voltage curve for thin film transistors having a channel layer without heat treatment. The absolute value of the difference between threshold voltages can be used to define the magnitude of the hysteresis value. In FIG. 5A, a thin film transistor 100 having the channel layer 130 with heat treatment is measured, and the magnitude of the hysteresis value is small. In FIG. 5B, a thin film transistor having the channel layer 130 without heat treatment is measured, and the magnitude of the hysteresis value is relative large. Therefore, the magnitude of hysteresis in the thin film transistor having the channel layer with heat treatment is smaller than the magnitude of hysteresis in the thin film transistor having the channel layer without heat treatment.

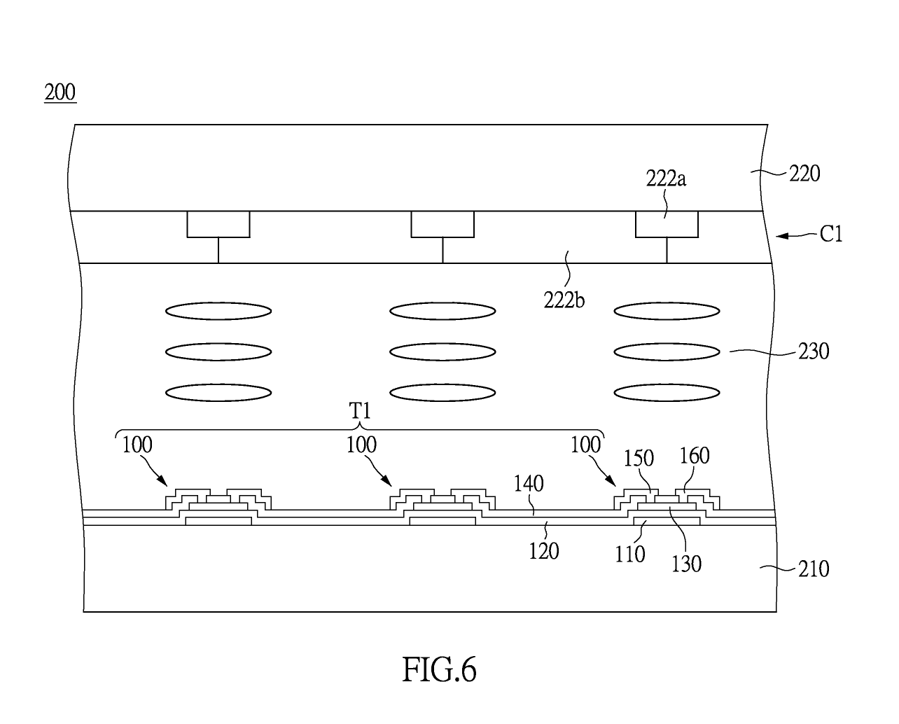

FIG. 6 illustrates a structural prospective view of a display panel in accordance with an embodiment of the instant disclosure. In this embodiment, the display panel 200 is a liquid crystal panel. Please refer to FIG. 6. The display panel 200 includes a first substrate 210, a second substrate 220, a liquid crystal layer 230, and an active element array layer T1. The liquid crystal layer 230 and the active element array layer T1 are disposed between the first substrate 210 and the second substrate 220. The active element array layer T1 includes at least one thin film transistor.

The first substrate 210 and the second substrate 220 are made of glass, plastic or quartz. The instant disclosure does not limit the materials of these substrates 210 and 220.

The display panel 200 can include a color filter layer C1 that is located on the second substrate 220. The color filter layer C1 includes light-shielding film 222a and a plurality of color filters 220b with various colors. The light-shielding film 222a shields light from a backlight module in order to avoid the effect in imagery caused by light leakage. Partial surface of the second substrate 220 is exposed through the light-shielding film 222a to be partitioned into a plurality of monochromatic pixel regions (not shown). The color filters 222b with various colors are disposed in the monochromatic or mono-color pixel regions. The materials of the light-shielding layer 222a may be black resin and black photoresist material, and so on. The color filters 222b are photoresists of various colors, and the material of the color filters 222b may be photoresist material. The color of the color filters 222b may be red, green, blue, transparent, and so on. For different product designs in the display panel, the configuration of the color filters 222b may be island type, mosaic type, delta type, and stripe type. The instant disclosure does not limit the color, materials, and configuration of color filters 222b.

The liquid crystal layer 230 is disposed at a gap between the first substrate 210 and the second substrate 220 in order to change the direction of the incident light. The liquid crystal layer 230 can be made of various types of materials, such as, nematic liquid crystals, smectic liquid crystals, cholesteric liquid crystals, and so on. However, the instant disclosure does not limit the types of materials of the liquid crystal layer 230.

The active element array layer T1, disposed on the first substrate 210, comprises a plurality of thin film transistors 100, a plurality of data lines (not shown), and a plurality of scan lines (not shown). The active element array layer Ti comprises thin film transistors 100 corresponding to the arrangement of the color filters 222b. The thin film transistor 100 includes the gate electrode 110, the gate insulating layer 120, the channel layer 130, the protective layer 140, the source electrode 150, and the drain electrode 160, all of which are sequentially formed on the first substrate 210. The protective layer 140 covers part of the channel layer 130 and exposes another parts of the channel layer 130 which are respectively electrically connected with the source electrode 150 and the drain electrode 160. The drain electrode 160 is connected to the date lines (not shown), and the gate electrode 110 is connected to the scan lines (not shown).

The material of the channel layer 130 in one of the embodiment of this invention is indium-gallium-zinc oxide. The instant disclosure does not limit the materials of channel layer 130. To be specific, the channel layer 130 can be made by different production procedures, such as magnetron sputtering, metal organic chemical-vapor deposition or pulsed laser deposition. After the deposition process, the channel layer 130 is heat treated, like annealing. The temperature of annealing treatment ranges between 200° C. and 400° C. Please refer to FIG. 1. The channel layer 130 can be separated into three portions from the front channel layer 130a to the back channel layer 130b: the first zone I, the second zone II and the third zone III. The first zone I represents the channel layer 130 proximate to the front channel layer 130a, the third zone III represents the channel layer 130 proximate to the back channel layer 130b, and the second zone II represents the intermediate layer 130c located between the front channel layer 130a and the back channel layer 130b. According to the variations in the first, second and third zones I, II, and III of curve L2, the oxygen vacancy concentrations in the first zone I and the third zone III are independently larger than the oxygen vacancy concentration in the second zone II. Namely, the oxygen vacancies in both of the front channel layer 130a and the back channel layer 130b are independently larger than oxygen vacancy in the intermediate layer 130c. In this way, most oxygen vacancies are present in the front channel layer 130a and the back channel layer 130b.

Notably, during the heat treatment of the channel layer 130, the oxygen vacancies presented in the intermediate layer 130c shift to the front channel layer 130a and the back channel layer 130b, so as to improve upon the hysteresis phenomenon. Therefore, the response speed of a liquid crystal display (LCD) and the flicker or image sticking is improved.

In summary, the instant disclosure provides the channel layer with annealing treatment after deposition. The temperature of annealing treatment ranges between 200° C. and 400° C. The front channel layer is defined as a portion of the channel layer proximate to a side of the gate insulating layer where the binding energy of the channel layer starts to shift. The back channel layer is defined as a portion of the channel layer proximate to a side of the source electrode and the drain electrode where the binding energy of the channel layer starts to shift. The channel layer 130 can be separated into three sections from the front channel layer 130a to the back channel layer 130b: the first zone, the second zone and the third zone. The first zone represents the channel layer proximate to the front channel layer, the third zone represents the channel layer proximate to the back channel layer, and the second zone represents the intermediate layer located between the front channel layer and the back channel layer. The oxygen vacancy concentrations in both of the first zone and the third zone are independently larger than oxygen vacancy concentration in the second zone. In this way, most oxygen vacancies are present in the front channel layer and the back channel layer. Notably, during the heat treatment, the oxygen vacancies presented in the intermediate layer shift to the front channel layer and the back channel layer, so as to improve the hysteresis phenomenon. Therefore, the response speed of a liquid crystal display and the flicker or image sticking are improved.

An embodiment of the instant disclosure provides a thin film transistor that is compatible with various display panels. The response speed of a liquid crystal display (LCD), the effect of hysteresis and the flicker or image sticking of the display panel can be improved.

The above-mentioned descriptions represent merely the exemplary embodiment of the instant disclosure, without any intention to limit the scope of the instant disclosure thereto. Various equivalent changes, alternations or modifications based on the claims of instant disclosure are all consequently viewed as being embraced by the scope of the present disclosure.

What is claimed is:

1. A thin film transistor comprises:
a gate electrode disposed on a substrate;
a channel layer electrically insulated from the gate electrode;
a gate insulating layer disposed between the gate electrode and the channel layer; and
a source electrode electrically connected to the channel layer; and
a drain electrode electrically connected to the channel layer;
wherein the channel layer comprises a front channel layer disposed proximate to a side of the gate insulating layer, a back channel layer proximate to a side of the source electrode and the drain electrode, and an intermediate layer disposed between the front channel layer and back channel layer, and an oxygen vacancy concentration of the front channel layer is greater than an oxygen vacancy concentration of the intermediate layer.

2. The thin film transistor according to claim 1, wherein the oxygen vacancy concentrations of the front channel layer and an oxygen vacancy concentration of the back channel layer are greater than the oxygen vacancy concentration of the intermediate layer.

3. The thin film transistor according to claim 1, further comprising:
a protective layer disposed between the source electrode, the drain electrode and the channel layer, and wherein the protective layer covers a part of the channel layer and exposes another part of the channel layer.

4. The thin film transistor according to claim 1, wherein the front channel layer is a portion of the channel layer proximate to the side of the gate insulating layer where a binding energy of the channel layer starts to shift.

5. The thin film transistor according to claim 1, wherein the thickness of the front channel layer is between 1 nanometer and 10 nanometers.

6. The thin film transistor according to claim 1, wherein the back channel layer is a portion of the channel layer proximate to the side of the source electrode and the drain electrode where a binding energy of the channel layer starts to shift.

7. The thin film transistor according to claim 1, wherein the thickness of the back channel layer is between 1 nanometer and 10 nanometers.

8. The thin film transistor according to claim 1, wherein the channel layer is a metal oxide semiconductor layer.

9. The thin film transistor according to claim 8, wherein the metal oxide semiconductor layer is made of indium-gallium-zinc oxide, and the ratio of indium, gallium, zinc and oxygen is respectively 1:1.45 to 1.8:1 to 1.25:4.3 to 4.7.

10. The thin film transistor according to claim 8, wherein the metal oxide semiconductor layer is made of Indium-Gallium-Zinc Oxide, and the oxygen vacancy concentration of the front channel layer and an oxygen vacancy concentration of the back channel layer independently range between 3% and 20%.

11. The thin film transistor according to claim 3, wherein the protective layer has a plurality of openings, the source electrode and the drain electrode are connected to the channel layer through the openings, and an oxygen vacancy concentration of the channel layer connected to the openings is greater than an oxygen vacancy concentration of the channel layer connected to the protective layer.

12. A display panel, comprising:
a first substrate;
a second substrate; and
an active element array layer disposed between the first substrate and the second substrate, and the active element array layer including a plurality of thin film transistors, at least one of the thin film transistors comprising:
a gate electrode disposed on the first substrate;
a channel layer electrically insulated from the gate electrode;
a gate insulating layer disposed between the gate electrode and the channel layer; and
a source electrode electrically connected to the channel layer; and
a drain electrode electrically connected to the channel layer;
wherein the channel layer comprises a front channel layer proximate to a side of the gate insulating layer, a back channel layer proximate to a side of the source electrode and the drain electrode, and an intermediate layer disposed between the front channel layer and the back channel layer, and an oxygen vacancy concentration of the front channel layer is greater than an oxygen vacancy concentration of the intermediate layer.

13. The display panel according to claim 12, wherein the oxygen vacancy concentration of the front channel layer and an oxygen vacancy concentration of the back channel layer are independently greater than the oxygen vacancy concentration of the intermediate layer.

14. The display panel according to claim 12, further comprising:
a protective layer disposed between the source electrode, the drain electrode and the channel layer, and wherein the protective layer covers a part of the channel layer and exposes another part of the channel layer.

15. The display panel according to claim 12, wherein the front channel layer is a portion of the channel layer proximate to the side of the gate insulating layer where a binding energy of the channel layer starts to shift.

16. The display panel according to claim 12, wherein the back channel layer is a portion of the channel layer proximate to the side of the source electrode and the drain electrode where a binding energy of the channel layer starts to shift.

17. The display panel according to claim 12, wherein the channel layer is a metal oxide semiconductor layer.

18. The display panel according to claim 17, wherein the metal oxide semiconductor layer is made of Indium-Gallium-Zinc Oxide, and the ratio of Indium, Gallium, Zinc and oxygen is respectively 1:1.45 to 1.8:1 to 1.25:4.3 to 4.7.

19. The display panel according to claim 17, wherein the metal oxide semiconductor layer is made of Indium-Gallium-Zinc Oxide, and the oxygen vacancy concentration of the front channel layer and an oxygen vacancy concentration of the back channel layer are independently between 3% and 20%.

20. The display panel according to claim 14, wherein the protective layer has a plurality of openings, and the source electrode and the drain electrode are connected to the channel layer through the openings, and an oxygen vacancy concentration of the channel layer connected to the openings is greater than an oxygen vacancy concentration of the channel layer connected to the protective layer.
